(19) United States
(12) Patent Application Publication
(10) Pub. No.: US 2015/0136592 A1
(43) Pub. Date: May 21, 2015

(54) Sintered Body and Sputtering Target

(71) Applicant: Mitsui Mining & Smelting Co., Ltd., Tokyo (JP)

(72) Inventor: Kyosuke Teramura, Omuta-shi (JP)

(21) Appl. No.: 14/406,891

(22) PCT Filed: Apr. 10, 2013
(86) PCT No.: PCT/JP2013/060822

§ 371 Date: Dec. 10, 2014

(30) Foreign Application Priority Data
Aug. 10, 2012 (JP) 2012-178338

(51) Int. Cl. H01J 37/34; C23C 14/34

(52) U.S. Cl. CPC H01J 37/3426; C23C 14/3414
USPC 204/298.13; 75/236

(57) ABSTRACT

Provided is a sintered body containing Fe, Pt, C and Ag, wherein, when a composition of Fe, Pt, C and Ag is represented by an expression: (Fe_{x/100}Pt_{(100-x)/100})_{100-y-z}Ag_{y}C_{z}, expressions: 35≦x≦65, 1≦y≦20 and 13≦z≦60 are satisfied, a relative density is in the range of 95% or more, an oxygen content is in the range of 700 ppm or less, and a major axis length of a phase composed of Ag is in the range of 20 μm or less, and a sputtering target obtained from the sintered body, having excellent film characteristics to allow formation of a thin film, for example, a high performance magnetic recording film.

### TECHNICAL FIELD

The present invention relates to a sintered body and a sputtering target therefrom, and more specifically, to an FePtC-based sintered body having a high density and a low oxygen content and having a uniform texture, and containing Ag being a low-melting point material, and also to a sputtering target therefrom.

### BACKGROUND ART

As a magnetic recording film constituting a hard disk or the like to be mounted in a computer or the like, a CoPt-based thin film has been used so far to achieve an increase in a recording density by a perpendicular magnetic recording system. However, a request for high-density recording has been recently intensified, and the CoPt-based thin film has become difficult in meeting the request.

Consequently, as a next-generation magnetic recording film alternative to the CoPt-based thin film, an FePt-based thin film has been proposed. The FePt-based thin film has an advantage of higher magnetic anisotropy in comparison with the CoPt-based thin film. A technique of adding carbon or the like to the FePt-based thin film has been adopted for the purpose of controlling film structure.

Moreover, in order to provide the FePt-based thin film with magnetic anisotropy, treatment is applied to the thin film for ordering FePt particles in the thin film by heating. A high temperature is needed for the above ordering treatment, and therefore high heat resistance is required for a substrate. Consequently, in order to lower the ordering temperature, a technique has been adopted for incorporating a low-melting point material such as Ag into the thin film.

Such a magnetic recording film is ordinarily formed by sputtering a sputtering target. Therefore, development has been desired for a high performance FePtAgC sputtering target or the like. These sputtering targets are ordinarily produced by a powder metallurgy process.

If the sputtering target does not have a high density, a large amount of gas is emitted from the sputtering target under a vacuum atmosphere during sputtering to cause a significant deterioration of characteristics of a thin film to be formed. Therefore, the sputtering target is required to have the high density. According to the powder metallurgy process, if firing temperature is increased, a high-density sputtering target is ordinarily obtained. In the case of an FePtC-based alloy, however, a melting point of a metallic phase: Fe—Pt is significantly different from a melting point of a semimetallic phase: C, and therefore a sufficient increase in the firing temperature is quite difficult, and thus achievement of high density is difficult by increasing the firing temperature. When the alloy contains a low-melting point material such as Ag, an increase in the firing temperature is furthermore quite difficult, and thus achievement of high density is further difficult.

Moreover, if the sputtering target has a high content of an impurity such as oxygen, characteristics of the thin film to be formed deteriorate, and therefore the target preferably contains no impurity as described above. However, Fe powder or the like used as a raw material is ordinarily oxidized on a surface to contain a surface oxidized layer. Therefore, difficulty exists in completely suppressing incorporation of oxygen into the sputtering target.

Further, if a sputtering target has a non-uniform texture, arcing or the like occurs during sputtering, and film characteristics deteriorate, for example, smoothness of the film obtained is adversely affected, and therefore the texture is preferably uniform.

As a method for achieving a high density of an FePtC-based sputtering target, a method is known in which a pre-sintered body produced by a pressure molding process such as a hot press (HP) process is subjected to hot isostatic press (HIP) treatment. When the pre-sintered body has a low density, the hot isostatic press treatment is applied by sealing the pre-sintered body into a SUS tube or the like. On the occasion, if an oxygen content in the pre-sintered body is high, a gas derived from oxygen contained in the pre-sintered body is emitted in a sealed tube during treatment to cause extreme difficulty in achieving the high density of the sputtering target. Moreover, if the oxygen content in the pre-sintered body is high, an oxygen content in the sputtering target obtained obviously increases.

Accordingly, when the sputtering target is produced by applying the hot isostatic press treatment to the pre-sintered body, the oxygen content in the pre-sintered body is preferably decreased for achieving the high density of the sputtering target, and also for decreasing the oxygen content in the sputtering target. As mentioned above, oxygen contained in the pre-sintered body is thought to be derived from the surface oxidized layer of Fe powder or the like mainly used as the raw material.

Therefore, the surface oxidized layer of Fe powder or the like is preferably reduced before the hot isostatic press treatment. The above reduction can be performed, for example, as described in Patent Literature 1, by heating Fe powder or the like under coexistence of C powder in an inert atmosphere. Moreover, the surface oxidized layer of Fe powder or the like is sufficiently reduced even by merely performing pressure sintering by hot press or the like upon forming the pre-sintered body. As a temperature for reducing the surface oxidized layer in the operations, 700 to 900° C. is ordinarily needed, although the temperature is different depending on an atmosphere. However, when the low-melting point material such as Ag is contained in the raw material, if a reduction operation is performed at the temperature as described above, agglomeration or elution of the low-melting point material occurs to cause extreme difficulty in producing a sintered body having an intended composition or cause texture coarsening in some cases.

The situation as describe above has caused difficulty in obtaining the FePtC-based sputtering target having the high density, the low oxygen content and the uniform texture and containing the low-melting point material such as Ag.

### CITATION LIST

### Patent Literature

Patent Literature 1: JP-A-H6-57365

### SUMMARY OF INVENTION

### Technical Problem

The present invention has been made to solve the problems of the conventional arts as described above, and an object of the present invention is to provide an FePtC-based sintered body containing Ag being a low-melting point material and having a high density, a low oxygen content and a uniform texture and a sputtering target therefrom.

### Solution to Problem

The present invention that attains the object described above concerns a sintered body containing Fe, Pt, C and Ag, wherein, when a composition of Fe, Pt, C and Ag is represented by an expression: (Fe_{x/100}Pt_{(100-x)/100})_{100-y-z}Ag_{y}C_{z}, expressions: 35≦x≦65, 1≦y≦20 and 13≦z≦60 are satisfied, a relative density is in the range of 95% or more, an oxygen content is in the range of 700 ppm or less, and a major axis length of a phase composed of Ag is in the range of 20 μm or less.

The sintered body is produced by applying hot isostatic press treatment to a pre-sintered body containing Fe, Pt, C and Ag.

Moreover, the sintered body is produced by applying the hot isostatic press treatment to a pre-sintered body containing Fe, Pt, C and Ag as prepared by a spark plasma sintering process.

The present invention also concerns a sputtering target obtained from the sintered body.

### Advantageous Effects of Invention

A sintered body of the present invention contains Fe, Pt, C and Ag, wherein a relative density is in the range of 95% or more, an oxygen content is in the range of 700 ppm or less, and a major axis length of a phase composed of Ag is in the range of 20 μm or less. Therefore, a sputtering target obtained from the sintered body has a high density, a low oxygen content and a uniform texture, and therefore a high performance thin film, for example, a high performance magnetic recording film can be formed.

### BRIEF DESCRIPTION OF DRAWINGS

FIG. 1 shows a mapping image of Ag as obtained by an energy dispersive X-ray analysis of a pre-sintered body obtained in Example 1.

FIG. 2 shows a mapping image of Ag as obtained by an energy dispersive X-ray analysis of a sintered body obtained in Example 1.

FIG. 3 shows a mapping image of Ag as obtained by an energy dispersive X-ray analysis of a pre-sintered body obtained in Comparative Example 1.

FIG. 4 shows a mapping image of Ag as obtained by an energy dispersive X-ray analysis of a sintered body obtained in Comparative Example 1.

FIG. 5 shows a mapping image of Ag as obtained by an energy dispersive X-ray analysis of a pre-sintered body obtained in Comparative Example 2.

FIG. 6 shows a mapping image of Ag as obtained by an energy dispersive X-ray analysis of a sintered body obtained in Comparative Example 2.

FIG. 7 shows a mapping image of Ag as obtained by an energy dispersive X-ray analysis of a pre-sintered body obtained in Comparative Example 4.

FIG. 8 shows a mapping image of Ag as obtained by an energy dispersive X-ray analysis of a sintered body obtained in Comparative Example 4.

FIG. 9 shows a mapping image of Ag as obtained by an energy dispersive X-ray analysis of a pre-sintered body obtained in Example 2.

FIG. 10 shows a mapping image of Ag as obtained by an energy dispersive X-ray analysis of a sintered body obtained in Example 2.

FIG. 11 shows a mapping image of Ag as obtained by an energy dispersive X-ray analysis of a pre-sintered body obtained in Example 3.

FIG. 12 shows a mapping image of Ag as obtained by an energy dispersive X-ray analysis of a sintered body obtained in Example 3.

FIG. 13 shows a mapping image of Ag as obtained by an energy dispersive X-ray analysis of a pre-sintered body obtained in Example 4.

FIG. 14 shows a mapping image of Ag as obtained by an energy dispersive X-ray analysis of a sintered body obtained in Example 4.

FIG. 15 shows a mapping image of Ag as obtained by an energy dispersive X-ray analysis of a pre-sintered body obtained in Example 5.

FIG. 16 shows a mapping image of Ag as obtained by an energy dispersive X-ray analysis of a sintered body obtained in Example 5.

FIG. 17 is a diagram showing one example of major axis length of a phase composed of Ag.

### DESCRIPTION OF EMBODIMENTS

### Sintered Body

A sintered body of the present invention contains Fe, Pt, C and Ag. The sintered body of the present invention contains Ag in addition to Fe, Pt and C, thereby allowing formation of a high performance magnetic recording film from a sputtering target obtained from the sintered body.

Elements constituting the sintered body according to the present invention include Fe, Pt, C and Ag, and in addition thereto, an inevitable impurity such as oxygen may be occasionally incorporated into the sintered body.

When a composition of Fe, Pt, C and Ag in a sintered body according to the present invention is represented by an expression: (Fe_{x/100}Pt_{(100-x)/100})_{100-y-z}Ag_{y}C_{z}, expressions: 35≦x≦65, 1≦y≦20 and 13≦z≦60 are satisfied. If the composition of Fe, Pt, C and Ag in a sintered body according to the present invention is in the above-described range, a high performance magnetic recording film can be formed using the sputtering target obtained from the sintered body. Then, x is preferably in the range of 45 to 55, y is preferably in the range of 2 to 15 and z is preferably in the range of 20 to 60.

In the sintered body of the present invention, an oxygen content is in the range of 700 ppm or less, preferably, in the range of 500 ppm or less, and further preferably, in the range of 300 ppm or less. If the oxygen content is in the range of 700 ppm or less, the high performance thin film can be formed using the sputtering target obtained from the sintered body. If the oxygen content is higher than 700 ppm, an impurity significantly increases, and such a high performance thin film is not obtained.

In the sintered body of the present invention, a relative density is in the range of 95% or more, preferably, in the range of 98% or more, and further preferably, in the range of 99% or more. If the relative density is in the range of 95% or more, the high performance thin film can be formed using the sputtering target obtained from the sintered body. If the relative density of the sintered body is lower than 95%, upon placing the sputtering target obtained from the sintered body in a vacuum atmosphere during sputtering, a large amount of gas is emitted from the sputtering target, and characteristics of the thin film formed by sputtering deteriorate. The relative density is expressed using a numeric value measured based on the Archimedian method.

In the sintered body of the present invention, a major axis length of a phase composed of Ag (hereinafter, also referred to as a Ag phase) to be incorporated into the sintered body is in the range of 20 μm or less, preferably, in the range of 10 μm or less, and further preferably, in the range of 5 μm or less. If the major axis length of the Ag phase is in the range of 20 μm or less, a texture of the sintered body is reasonably uniform, and film-forming properties of the sputtering target obtained from the sintered body are improved. If the major axis length of the Ag phase is larger than 20 μm, the Ag phase is coarsened, and the texture is reasonably non-uniform. If sputtering is performed using the sputtering target obtained from the sintered body, arcing or the like easily occurs, and film characteristics deteriorate, for example, smoothness of the film obtained is adversely affected.

The major axis length of the Ag phase is determined using a scanning electron microscope (SEM) and an energy dispersive X-ray analysis (EDX).

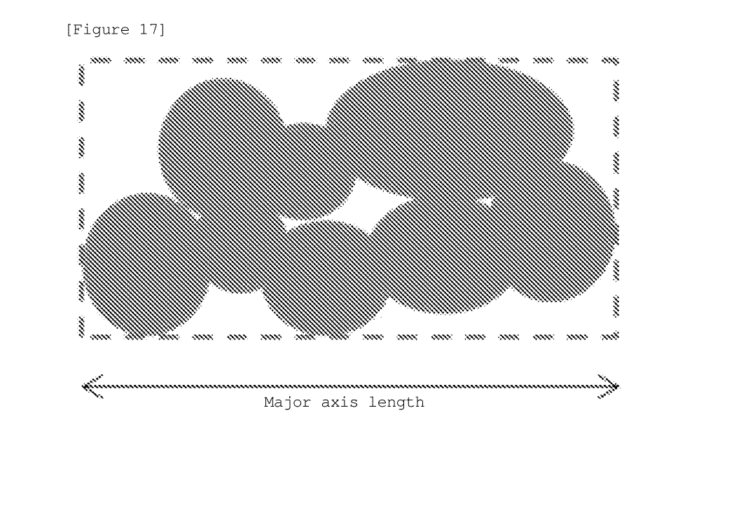

The major axis length of the Ag phase means, when one Ag phase confirmed by the energy dispersive X-ray analysis is framed by a rectangle to be in a minimum area, a length of a long side of the rectangle. One Ag phase means a phase linked with only Ag without being divided by any other phase. The rectangle to be in the minimum area means the rectangle having the minimum area among rectangles enveloping an outer edge of one Ag phase (including a case where a side of the rectangle comes in contact with the outer edge of the Ag phase). As one example, FIG. 17 shows a major axis length of a Ag phase. In FIG. 17, a part displayed in grey shows one Ag phase confirmed by the energy dispersive X-ray analysis, a rectangle shown by a dotted line refers to the rectangle to be in the minimum area, and the length of the long side of the rectangle refers to the major axis length of the Ag phase.

Specifically, a scanning electron microscope is used to observe the present sintered body at a magnification of 1,000 times to take a micrograph, thereby obtaining a SEM image of an area of about 100 μm×130 μm, for example. An energy dispersive X-ray analysis is conducted to a region of the SEM image to give a mapping image of Ag. When each Ag phase confirmed using the mapping image is framed by a rectangle to be in a minimum area, a length of a long side of the rectangle in a largest area (hereinafter, referred to as a maximum rectangle) among the rectangles is determined using a scale on the mapping image. When judgment is difficult as to whether or not a phase and another phase are separated in the mapping image due to a poor resolution or the like, judgment is made using the SEM image. When a place corresponding to Ag in the mapping image is carefully observed in the SEM image, the place can be confirmed to have contrast different from the contrast of any other phase, thereby allowing judgment as to whether the phase and the other phase are overlapped. The microscope observation is conducted five times at random, and the length of the long side of the maximum rectangle is determined for every observation by the technique, and a maximum value of the lengths is taken as the major axis length of the Ag phase.

The major axis length of the phase composed of Ag being in the range of 20 μm or less in the present invention means that the thus obtained major axis length of the Ag phase is in the range of 20 μm or less.

### Method for Producing Sintered Body

The sintered body can be produced by a production method comprising Steps (I) and (II) as described below, for example.

Step (I): A step for mixing Fe powder, Pt powder, C powder and Ag powder to prepare mixed powder, and sintering the mixed powder by a spark plasma sintering (SPS) process to give a pre-sintered body.

Step (II): A step for applying hot isostatic press treatment to the pre-sintered body to give a sintered body.

In the present invention, a body obtained by sintering raw material powder by a sintering process such as the spark plasma sintering process is referred to as the pre-sintered body, and a body obtained by applying the hot isostatic press treatment to the pre-sintered body is referred to as the sintered body.

The method for producing the sintered body allows production of the sintered body having the high density, the low oxygen content and the uniform texture, and composed of Fe, Pt, C and Ag, wherein the relative density is in the range of 95% or more, the oxygen content is in the range of 700 ppm or less, and the major axis length of the phase composed of Ag is in the range of 20 μm or less.

According to the powder metallurgy process, a higher firing temperature has been known so far to ordinarily give a pre-sintered body having a higher density. However, in the case of the FePtC-base, the melting point of the metallic phase: Fe—Pt is significantly different from the melting point of the semimetallic phase: C, and therefore the sufficient increase in the firing temperature is quite difficult. When the low-melting point material such as Ag is contained therein, the increase in the firing temperature is furthermore quite difficult. When the pre-sintered body of FePtAgC is produced, the firing temperature is ordinarily in the range of 700 to 900° C. in the hot press process that has been applied so far as the firing process, and the relative density of the pre-sintered body obtained in the temperature range is ordinarily in the range of about 75 to 85%, and the pre-sintered body having the high density is quite difficult to obtain.

If the spark plasma sintering process is employed as the firing process, the pre-sintered body having the high relative density of about 85 to 95% can be obtained even at the low firing temperature as described above. Such an effect is thought to be obtained because the spark plasma sintering process allows bonding and sintering of particles with each other by spark plasma action caused between the particles of the raw material powder, and therefore energy required is small, thereby allowing sintering at a lower temperature in comparison with the hot press process or the like. As a result, the pre-sintered body having the high relative density is obtained in Step (I) according to the method for producing the sintered body. A sintered body having a still higher relative density can be obtained by providing the pre-sintered body having the high relative density for the hot isostatic press treatment in Step (II).

Moreover, the method has been so far known in which the sintered body having the high density is obtained by applying the hot isostatic press treatment to the pre-sintered body. According to the method, if the oxygen content in the pre-sintered body is high, the gas is emitted within the sealed tube during the hot isostatic press treatment to cause extreme difficulty in achieving the high density of the sintered body, and therefore the surface oxidized layer of Fe or the like is needed to be reduced before the hot isostatic press treatment. If the oxygen content in the pre-sintered body is high, the oxygen content in the sintered body obtained also increases. Therefore, the surface oxidized layer of Fe or the like is needed to be reduced also for obtaining the sintered body having the low oxygen content.

The above reduction can be performed by heating Fe or the like under coexistence of C in the inert atmosphere. Moreover, such reduction can be also performed even by firing by the hot press process or the like upon producing the pre-sintered body. However, in order to reduce the surface oxidized layer in the operations, treatment in the range of 700 to 900° C. is ordinarily needed. When the low-melting point material such as Ag is contained in the raw material, if treatment is applied at such temperature, agglomeration or elution of the low-melting point material occurs to cause extreme difficulty in producing the sintered body having the intended composition or cause texture coarsening in some cases.

When the spark plasma sintering process is employed as the firing process, even if firing is made at the temperature described above, agglomeration or elution of the low-melting point material such as Ag is not caused to allow sufficient reduction, and cause no texture coarsening. Therefore, the pre-sintered body having the low oxygen content and the uniform texture is obtained in Step (I) according to the method for producing the sintered body. Such an effect is thought to be obtained because an oxidized layer on a surface of the particles is removed by spark plasma action or a period of firing time can be shortened according to the spark plasma sintering process. As a result, the sintered body having the high relative density, the low oxygen content and the uniform texture is obtained according to the method for producing the sintered body.

### (Step (I))

In Step (I), the Fe powder, the Pt powder, the C powder and the Ag powder are mixed to prepare the mixed powder, and the mixed powder is sintered by the spark plasma sintering process to give the pre-sintered body.

A mean particle diameter of the Fe powder as measured by a BET (Brunauer-Emmett-Teller) method is ordinarily in the range of 10 to 70 μm. A mean particle diameter of the Pt powder as measured by the BET method is ordinarily in the range of 1 to 4 μm. A mean particle diameter of the C powder as measured by the BET method is ordinarily in the range of 3 to 20 μm. A mean particle diameter of the Ag powder as measured by the BET method is ordinarily in the range of 2 to 5 μm.

Each ratio of the Fe powder, the Pt powder, the C powder and the Ag powder in the mixed powder is determined such that compositions of Fe, Pt and C contained in the sintered body obtained are within the above-described ranges. In addition, according to the method for producing the sintered body, ratios of the Fe powder, the Pt powder, the C powder and the Ag powder in the mixed powder are confirmed to coincide with ratios of Fe, Pt, C and Ag in a sintered body obtained, respectively.

A method for mixing the Fe powder, the Pt powder, the C powder and the Ag powder is not particularly restricted, and specific examples include mixing by a ball mill.

The mixed powder is filled into a sintering die for a spark plasma sintering apparatus. The sintering die is made from graphite, for example. A size and shape of the sintering die can be appropriately selected according to a purpose.

A pressure during firing in spark plasma sintering is ordinarily in the range of 20 to 60 MPa, and preferably, in the range of 35 to 50 MPa. A firing temperature in the spark plasma sintering is ordinarily in the range of 700 to 900° C., and preferably, in the range of 800 to 900° C. A heating rate in the spark plasma sintering is ordinarily in the range of 10 to 100° C./min, and preferably, in the range of 30 to 100° C./min. A retention time at the firing temperature in the spark plasma sintering is ordinarily in the range of 5 to 180 minutes, and preferably, in the range of 10 to 60 minutes.

As mentioned above, the pre-sintered body having the high relative density, the low oxygen content and the uniform texture is obtained in Step (I) by performing the spark plasma sintering under the conditions described above.

The pre-sintered body obtained in Step (I) is further increased in the relative density by the hot isostatic press treatment in Step (II) to form the sintered body. A higher relative density of the pre-sintered body gives a sintered body having a higher relative density. The relative density of the pre-sintered body is preferably in the range of 85% or more, and further preferably, in the range of 90% or more.

As mentioned above, a lower oxygen content in the pre-sintered body obtained in Step (I) gives a sintered body having a higher relative density, a lower oxygen content, and a further uniform texture by the hot isostatic press treatment in Step (II). The oxygen content in the pre-sintered body is preferably in the range of 1,000 ppm or less, and further preferably, in the range of 700 ppm or less.

### (Step (II))

In Step (II), the pre-sintered body is subjected to the hot isostatic press treatment to give the sintered body.

The pre-sintered body is inserted into a pressure vessel such as a SUS tube, and subjected to the hot isostatic press treatment under the conditions described below.

A pressure is ordinarily in the range of 80 to 117 MPa, and preferably, in the range of 95 to 117 MPa. A treatment temperature is ordinarily in the range of 800 to 950° C., and preferably, in the range of 800 to 900° C. A retention time is ordinarily in the range of 0.5 to 3 hours, and preferably, in the range of 0.5 to 1 hour.

As mentioned above, the sintered body having the high relative density, the low oxygen content and the uniform texture is obtained by applying the hot isostatic press treatment under the conditions described above.

### Sputtering Target

The sputtering target can be obtained by appropriately applying processing, when necessary, to the sintered body. The sputtering target has the high relative density, the low oxygen content and the uniform texture, and therefore film-forming properties are satisfactory. A high quality thin film composed of Fe, Pt, C and Ag is obtained by sputtering the sputtering target, and may be suitably used for the magnetic recording film or the like.

### EXAMPLES

### Example 1

### Production of Pre-Sintered Body

Fe powder having a mean particle diameter of 30 μm, Pt powder having a mean particle diameter of 1 μm, Ag powder having a mean particle diameter of 2 μm and C powder having a mean particle diameter of 5 μm were mixed using a ball mill for 1.5 hours to achieve a content ratio of 25 mol %, 25 mol %, 10 mol % and 40 mol %, respectively, to prepare mixed powder. Each mean particle diameter described above was expressed by a numeric value measured by a BET method.

The resultant mixed powder was filled into a sintering die made from graphite, and fired using a spark plasma sintering apparatus under conditions described below to give a disc-shaped pre-sintered body having a diameter of 35 mm and a thickness of 4 mm.

### <Spark Plasma Sintering (SPS) Conditions>

Sintering atmosphere: vacuum

Heating rate: 70° C./min

Sintering temperature: 900° C.

Sintering retention time: 10 minutes

Pressure: 40 MPa

Temperature fall: Natural cooling in a furnace

### (Production of Sintered Body)

The resultant pre-sintered body was sealed into a pressure vessel made from a SUS tube, and subjected to hot isostatic press treatment using a hot isostatic press apparatus under conditions described below to give a disc-shaped sintered body having a diameter of 30 mm and a thickness of 3 mm.

### <Hot Isostatic Press Treatment Conditions>

Pressure: 117 MPa

Treatment temperature: 900° C.

Retention time: 1 hour

### (Determination of Values of Physical Properties of Pre-Sintered Body and Sintered Body)

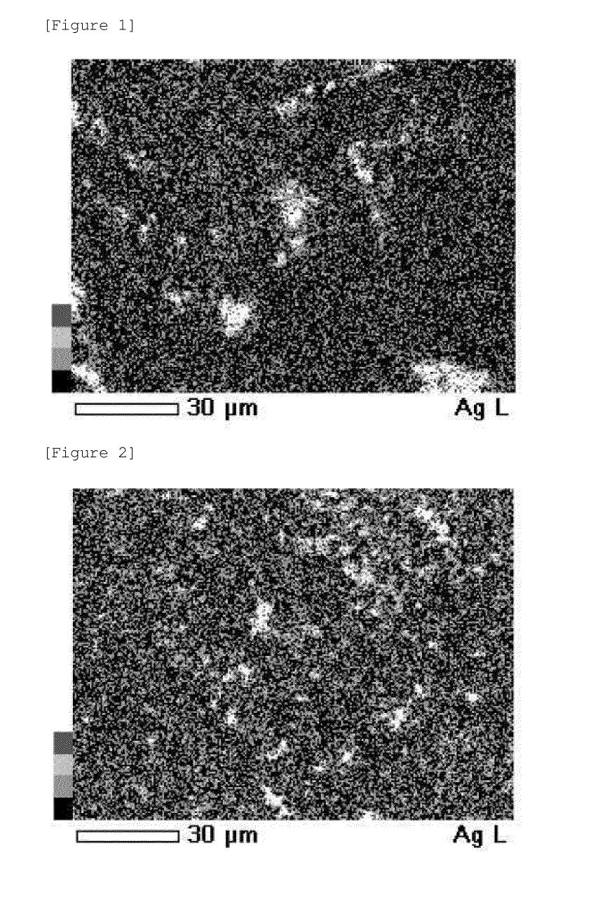

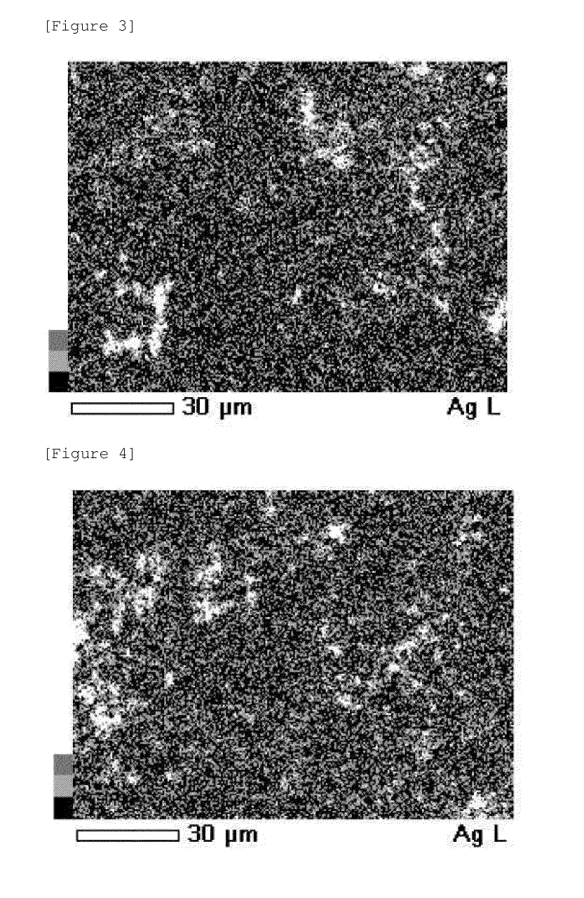

A relative density and an oxygen content were determined for the pre-sintered body, and a relative density, an oxygen content and a major axis length of a Ag phase were determined for the sintered body by measuring methods described below. Table 1 shows the results. Table 1 shows values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 1 shows one example of a mapping image of Ag in a pre-sintered body in a method for measuring a major axis length of a Ag phase as described below, and FIG. 2 shows one example of a mapping image of Ag in a sintered body in a method for measuring a major axis length of a Ag phase as described below. In FIGS. 1 and 2, a part palely displayed shows the Ag phase. In FIGS. 3 to 16 as described below, a part palely displayed also shows a Ag phase.

### <Measurement of Relative Density>

A relative density of a pre-sintered body and a sintered body was measured based on the Archimedian method. Specifically, a weight-in-air of the pre-sintered body or the sintered body was divided by a volume (weight-in-water of the pre-sintered body or the sintered body/water specific gravity at a measuring temperature), and a value expressed in percentage based on a theoretical density ρ (g/cm³) according to Formula (X) described below was taken as the relative density (unit: %).

$$\begin{matrix}[ Formula 1 ] & \\ ρ ≡ {( \frac{{C}_{1} / 100}{{ρ}_{1}} + \frac{{C}_{2} / 100}{{ρ}_{2}} + ⋯ + \frac{{C}_{i} / 100}{{ρ}_{i}} )}^{- 1} & ( X )\end{matrix}$$

(In Formula (X), C₁ to Cᵢ represent a content (% by weight) of a constituent material of a sintered body or a sintered body, respectively, and ρ₁ to ρᵢ represent a density (g/cm³) corresponding to C₁ to Cᵢ with regard to each constituent material)

### <Oxygen Content>

A surface of a pre-sintered body and a sintered body was cut by machining, and an oxygen content was determined from the resultant chip using an oxygen/nitrogen analyzer (EMGA-550, manufactured by HORIBA, Ltd.).

### <Major Axis Length of Ag Phase>

A scanning electron microscope (JXA-8800-R, manufactured by JEOL Ltd.) was used to observe a pre-sintered body and a sintered body at a magnification of 1,000 times under conditions of an accelerating voltage of 15 kV and an electron current of 0.05 μA to take a micrograph, thereby obtaining SEM images each of an area of about 100 μm×130 μm. An X-ray analysis was conducted to each region of the SEM images of the pre-sintered body and the sintered body using an energy dispersive X-ray analyzer (manufactured by JEOL Ltd.) to give mapping images of Fe, Pt, C and Ag. A length of a long side of a maximum rectangle obtained when each Ag phase confirmed by the mapping image was framed by a rectangle to be in a minimum area was determined using a scale on the mapping image. The above operations were performed five times at random, and a maximum value of the length of the long side of the maximum rectangle as obtained for every observation was taken as “major axis length of the Ag phase” and shown in Table 1.

### Comparative Example 1

### Production of Pre-Sintered Body

A disc-shaped pre-sintered body having a diameter of 35 mm and a thickness of 4 mm was obtained by performing an operation in a manner similar to the operation in Example 1 except that a sintering temperature of spark plasma sintering conditions was changed to 700° C.

### (Production of Sintered Body)

A disc-shaped sintered body having a diameter of 30 mm and a thickness of 3 mm was obtained by performing an operation to the resultant pre-sintered body in a manner similar to the operation in Example 1.

### (Determination of Values of Physical Properties of Pre-Sintered Body and Sintered Body)

A relative density and an oxygen content were determined for the pre-sintered body, and a relative density, an oxygen content and a major axis length of a Ag phase were determined for the sintered body by measuring methods similar to the methods in Example 1. Table 1 shows the results. Table 1 shows values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 3 shows one example of a mapping image of Ag in a pre-sintered body in a method for measuring a major axis length of a Ag phase as described above, and FIG. 4 shows one example of a mapping image of Ag in a sintered body in a method for measuring a major axis length of a Ag phase as described above.

### Comparative Example 2

### Production of Pre-Sintered Body

A disc-shaped pre-sintered body having a diameter of 35 mm and a thickness of 4 mm was obtained by performing an operation in a manner similar to the operation in Example 1 except that a sintering temperature of spark plasma sintering conditions was changed to 800° C.

### (Production of Sintered Body)

A disc-shaped sintered body having a diameter of 30 mm and a thickness of 3 mm was obtained by performing an operation to the resultant pre-sintered body in a manner similar to the operation in Example 1.

### (Determination of Values of Physical Properties of Pre-Sintered Body and Sintered Body)

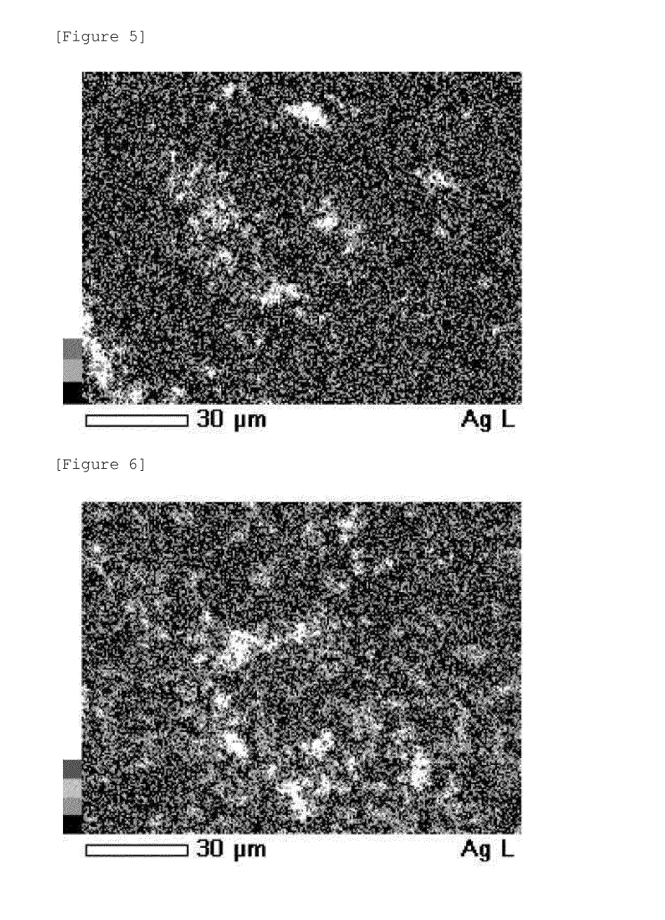

A relative density and an oxygen content were determined for the pre-sintered body, and a relative density, an oxygen content, and a major axis length of a Ag phase were determined for the sintered body by measuring methods similar to the methods in Example 1. Tables 1 and 2 show the results. Tables 1 and 2 show values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 5 shows one example of a mapping image of Ag in a pre-sintered body presented in the method for measuring the major axis length of the Ag phase as described above, and FIG. 6 shows one example of a mapping image of Ag in a sintered body in the method for measuring the major axis length of the Ag phase as described above.

### Comparative Example 3

### Production of Pre-Sintered Body

A disc-shaped pre-sintered body having a diameter of 35 mm and a thickness of 4 mm was obtained by performing an operation in a manner similar to the operation in Example 1 except that a sintering temperature of spark plasma sintering conditions was changed to 920° C. In the above operation, Ag powder melted during spark plasma sintering to cause elution of Ag.

### (Determination of Values of Physical Properties of Pre-Sintered Body)

A relative density and an oxygen content in the pre-sintered body were determined by measuring methods similar to the methods in Example 1. Table 1 shows the results.

### Comparative Example 4

### Production of Pre-Sintered Body

Fe powder having a mean particle diameter of 30 μm, Pt powder having a mean particle diameter of 1 μm, Ag powder having a mean particle diameter of 2 μm and C powder having a mean particle diameter of 5 μm were mixed using a ball mill for 1.5 hours to achieve a content ratio of 25 mol %, 25 mol %, 10 mol % and 40 mol %, respectively, to prepare mixed powder. Each mean particle diameter described above was expressed by a numeric value measured by a BET method.

A disc-shaped pre-sintered body having a diameter of 35 mm and a thickness of 4 mm was obtained by firing the resultant mixed powder using a hot press apparatus under conditions described below.

### <Hot Press (HP) Conditions>

Sintering atmosphere: Ar

Heating rate: 15° C./min

Sintering temperature: 900° C.

Sintering retention time: 60 minutes

Pressure: 40 MPa

Temperature fall: Natural cooling in a furnace

### (Production of Sintered Body)

A disc-shaped sintered body having a diameter of 30 mm and a thickness of 3 mm was obtained by performing an operation to the resultant pre-sintered body in a manner similar to the operation in Example 1.

### (Determination of Values of Physical Properties of Pre-Sintered Body and Sintered Body)

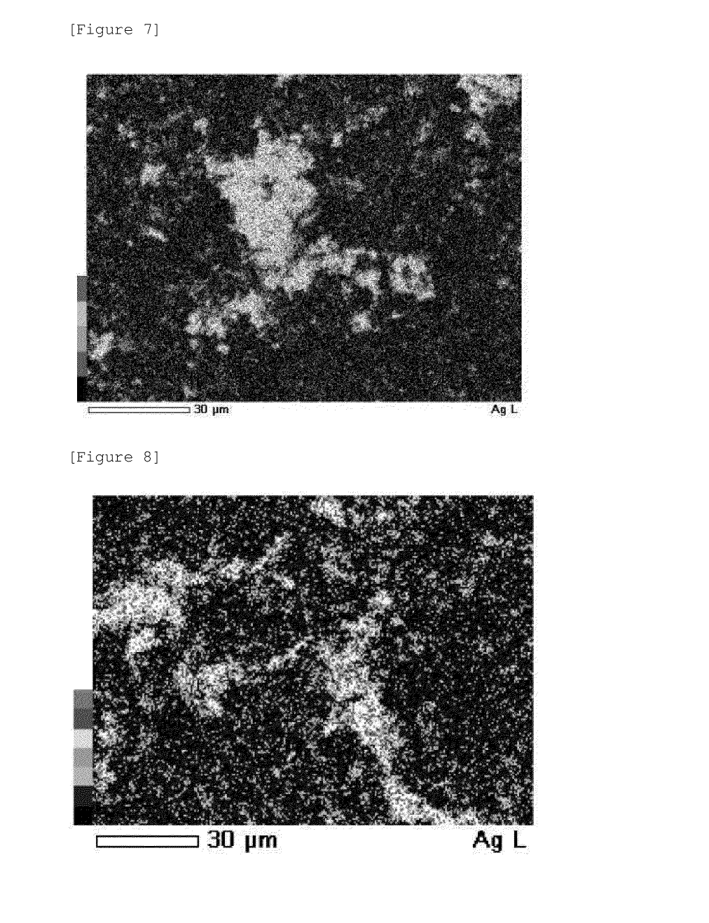

A relative density and an oxygen content were determined for the pre-sintered body, and a relative density, an oxygen content and a major axis length of a Ag phase were determined for the sintered body by measuring methods similar to the methods in Example 1. Table 2 shows the results. Table 2 shows values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 7 shows one example of a mapping image of Ag in a pre-sintered body presented in the method for measuring the major axis length of the Ag phase as described above, and FIG. 8 shows one example of a mapping image of Ag in a sintered body in the method for measuring the major axis length of the Ag phase as described above.

TABLE 1

| | | | | Pre-sintered body | | | Sintered Body | | | | | |
|---|---|---|---|---|---|---|---|---|---|---|---|---|
| | | | Sintering | | | Major Axis | | | | | | Major Axis |
| | Sintering | Heating | retention | Relative | Oxygen | Length of | | | | Relative | Oxygen | Length of |
| | Temperature | Rate | Time | Density | Content | Ag Phase | Composition | | | Density | Content | Ag Phase |
| | (° C.) | (° C./min) | (min) | (%) | (ppm) | (μm) | x | y | z | (%) | (ppm) | (μm) |
| Comparative | 700 | 70 | 10 | 92.27 | 4,700 | 15.0 | 50 | 10 | 40 | 98.39 | 1,200 | 16.2 |
| Example 1 | | | | | | | | | | | | |
| Comparative | 800 | 70 | 10 | 92.21 | 3,100 | 12.0 | 50 | 10 | 40 | 98.70 | 1,600 | 12.2 |
| Example 2 | | | | | | | | | | | | |
| Example 1 | 900 | 70 | 10 | 95.26 | 960 | 15.0 | 50 | 10 | 40 | 99.02 | 620 | 15.4 |
| Comparative | 920 | 70 | 10 | 89.82 | 390 | — | — | — | — | — | — | — |
| Example 3 | | | | | | | | | | | | |

TABLE 2

| | | | | Pre-sintered body | | | Sintered Body | | | | | |
|---|---|---|---|---|---|---|---|---|---|---|---|---|
| | | | Sintering | | | Major Axis | | | | | | Major Axis |
| | Sintering | Heating | Retention | Relative | Oxygen | Length of | | | | Relative | Oxygen | Length of |
| | Temperature | Rate | Time | Density | Content | Ag Phase | Composition | | | Density | Content | Ag Phase |
| | (° C.) | (° C./min) | (min) | (%) | (ppm) | (μm) | x | y | z | (%) | (ppm) | (μm) |
| Example 1 | 900 | 70 | 10 | 95.26 | 960 | 15.0 | 50 | 10 | 40 | 99.02 | 620 | 15.4 |
| Comparative | 900 | 70 | 10 | 87.75 | 310 | 38.3 | 50 | 10 | 40 | 94.76 | 270 | 41.4 |
| Example 4 | | | | | | | | | | | | |

Table 1 shows values of physical properties of the temporarily sintered bodies obtained by performing the spark plasma sintering at various sintering temperatures, and the sintered bodies obtained by applying the hot isostatic press treatment to the temporarily sintered bodies.

As shown in Table 1, when the spark plasma sintering temperature was 700, 800 and 900° C., a pre-sintered body having a relative density as high as 92% or more was obtained. Moreover, when the sintering temperature was in the range of 700 to 900° C., as the sintering temperature was higher, a pre-sintered body having a higher relative density was obtained. When the sintering temperature was 920° C., elution of Ag occurred, and the relative density of the pre-sintered body did not increase, and was in the range of 90% or less.

When the spark plasma sintering temperature was in the range of 700 to 920° C., as the sintering temperature was higher, the oxygen content in the pre-sintered body decreased.

The pre-sintered body obtained when the spark plasma sintering temperature was 900° C. was subjected to the hot isostatic press treatment to give a sintered body having a relative density as high as 98% or more and an oxygen content as low as 700 ppm or less, and to give a sintered body having a major axis length of Ag in the range of 20 μm or less and a uniform texture. When the sintering temperature was in the range of 700 to 900° C., as the sintering temperature was higher, a sintered body having a higher relative density and a lower oxygen content was obtained. When the sintering temperature was in the range of 700 to 900° C., as the oxygen content in the pre-sintered body was lower, a sintered body having a lower oxygen content was obtained. At the sintering temperature of 700° C. and 800° C., a sintered body having a relative density as high as 98% or more was obtained. However, the oxygen content in the pre-sintered body was high, and therefore a sintered body having an oxygen content as low as 700 ppm or less was not obtained.

In Table 2, a comparison is made between the results of a pre-sintered body obtained by performing spark plasma sintering at a sintering temperature of 900° C. and a sintered body obtained by applying hot isostatic press treatment to the pre-sintered body, and the results of a pre-sintered body obtained by performing hot press at a sintering temperature of 900° C. and a sintered body obtained by applying hot isostatic press treatment to the pre-sintered body.

As shown in Table 2, the pre-sintered body obtained by applying the spark plasma sintering and the sintered body obtained therefrom had a higher relative density in comparison with the pre-sintered body obtained by applying the hot press and the sintered body obtained therefrom, respectively. The pre-sintered body obtained by applying the hot press and the sintered body obtained therefrom had a lower oxygen content in comparison with the pre-sintered body obtained by applying the spark plasma sintering and the sintered body obtained therefrom. The above is thought to be resulted from a lower heating rate and a longer period of time during CO gas emitted from the mixed powder during sintering in the hot press. As mentioned above, the lower oxygen content in the pre-sintered body allows achievement of the higher density by the hot isostatic press treatment. However, in Comparative Example 4, the relative density of the pre-sintered body was low, and therefore a relative density as high as the relative density in Example 1 was presumably not obtained even by performing the hot isostatic press treatment.

As shown in Table 2, the sintered body obtained by applying the hot press had a larger major axis length of the Ag phase in comparison with the sintered body obtained by applying the spark plasma sintering. The above is thought to be resulted from growth of the Ag phase to be coarsened due to a longer period of sintering time in the hot press in comparison with the spark plasma sintering. On the contrary, a smaller major axis length of the Ag phase in the spark plasma sintering is thought to be resulted from a shorter period of sintering time due to completion of firing before coarsening of the Ag phase.

From Table 2, the hot isostatic press treatment of the pre-sintered body obtained by spark plasma sintering is found to give a sintered body having a higher density and a further uniform texture in comparison with a case where the pre-sintered body obtained by the hot press was subjected to the hot isostatic press treatment.

### Example 2

### Production of Pre-Sintered Body

Mixed powder was prepared in a manner similar to the operation in Example 1 except that content ratios of Fe powder, Pt powder, Ag powder and C powder were changed to 34.2 mol %, 41.8 mol %, 4 mol % and 20 mol %, respectively.

The resultant mixed powder was fired using a spark plasma sintering apparatus under conditions similar to the conditions in Example 1 except that a heating rate was changed to 50° C./min and a sintering retention time was changed to 30 minutes to give a disc-shaped pre-sintered body having a diameter of 170 mm and a thickness of 5 mm.

### (Production of Sintered Body)

The resultant pre-sintered body was sealed into a pressure vessel made from a SUS tube, and subjected to hot isostatic press treatment using a hot isostatic press apparatus under conditions similar to the conditions in Example 1 to give a disc-shaped sintered body having a diameter of 165 mm and a thickness of 4 mm.

### (Determination of Values of Physical Properties of Pre-Sintered Body and Sintered Body)

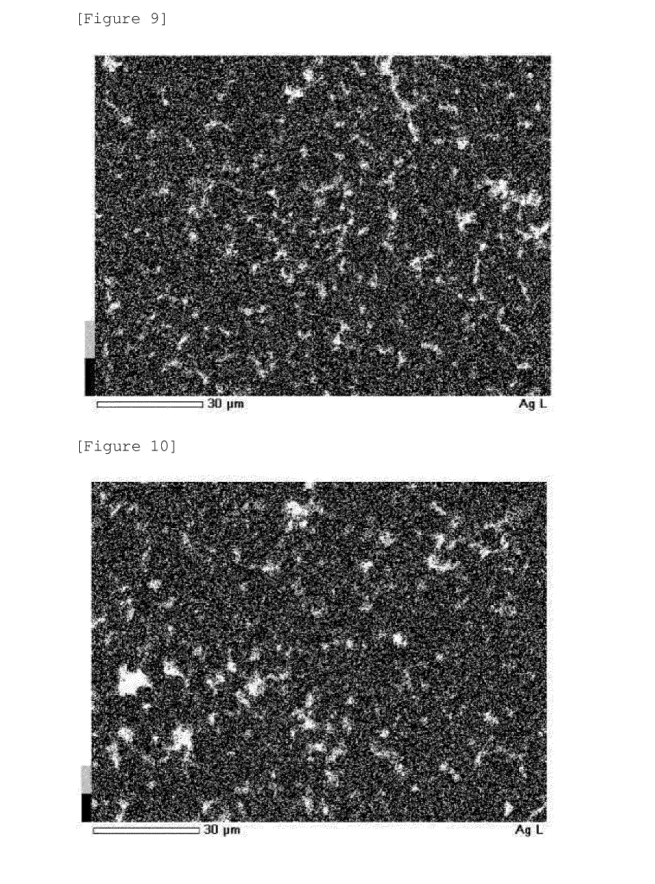

A relative density and an oxygen content were determined for the pre-sintered body, and a relative density, an oxygen content and a major axis length of a Ag phase were determined for the sintered body by measuring methods described below. Table 3 shows the results. Table 3 shows values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 9 shows one example of a mapping image of Ag in a pre-sintered body in a method for measuring a major axis length of a Ag phase as described below, and FIG. 10 shows one example of a mapping image of Ag in a sintered body in a method for measuring a major axis length of a Ag phase as described below.

### Example 3

### Production of Pre-Sintered Body

Mixed powder was prepared in a manner similar to the operation in Example 1 except that content ratios of Fe powder, Pt powder, Ag powder and C powder were changed to 29.7 mol %, 24.3 mol %, 6 mol % and 40 mol %, respectively.

The resultant mixed powder was fired using a spark plasma sintering apparatus under conditions similar to the conditions in Example 1 except that a heating rate was changed to 50° C./min and a sintering retention time was changed to 30 minutes to give a disc-shaped pre-sintered body having a diameter of 170 mm and a thickness of 5 mm.

### (Production of Sintered Body)

The resultant pre-sintered body was sealed into a pressure vessel made from a SUS tube, and subjected to hot isostatic press treatment using a hot isostatic press apparatus under conditions similar to the conditions in Example 1 to give a disc-shaped sintered body having a diameter of 165 mm and a thickness of 4 mm.

### (Determination of Values of Physical Properties of Pre-Sintered Body and Sintered Body)

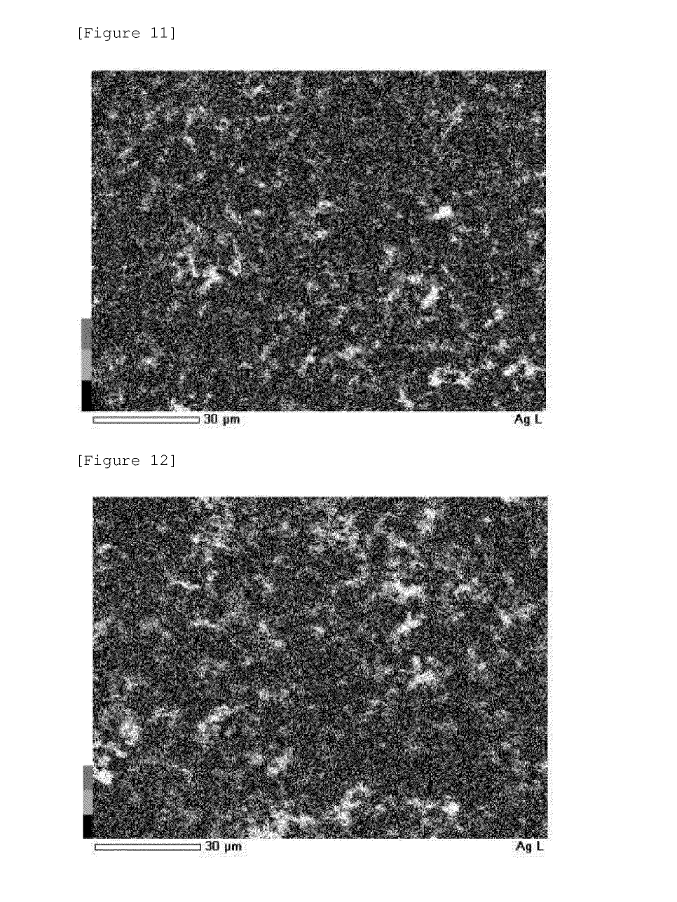

A relative density and an oxygen content were determined for the pre-sintered body, and a relative density, an oxygen content and a major axis length of a Ag phase were determined for the sintered body by measuring methods described below. Table 3 shows the results. Table 3 shows values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 11 shows one example of a mapping image of Ag in a pre-sintered body in a method for measuring a major axis length of a Ag phase as described below, and FIG. 12 shows one example of a mapping image of Ag in a sintered body in a method for measuring a major axis length of a Ag phase as described below.

### Example 4

### Production of Pre-Sintered Body

Mixed powder was prepared in a manner similar to the operation in Example 1 except that content ratios of Fe powder, Pt powder, Ag powder and C powder were changed to 26 mol %, 26 mol %, 8 mol % and 40 mol %, respectively.

The resultant mixed powder was fired using a spark plasma sintering apparatus under conditions similar to the conditions in Example 1 except that a heating rate was changed to 50° C./min and a sintering retention time was changed to 30 minutes to give a disc-shaped pre-sintered body having a diameter of 170 mm and a thickness of 5 mm.

### (Production of Sintered Body)

The resultant pre-sintered body was sealed into a pressure vessel made from a SUS tube, and subjected to hot isostatic press treatment using a hot isostatic press apparatus under conditions similar to the conditions in Example 1 to give a disc-shaped sintered body having a diameter of 165 mm and a thickness of 4 mm.

### (Determination of Values of Physical Properties of Pre-Sintered Body and Sintered Body)

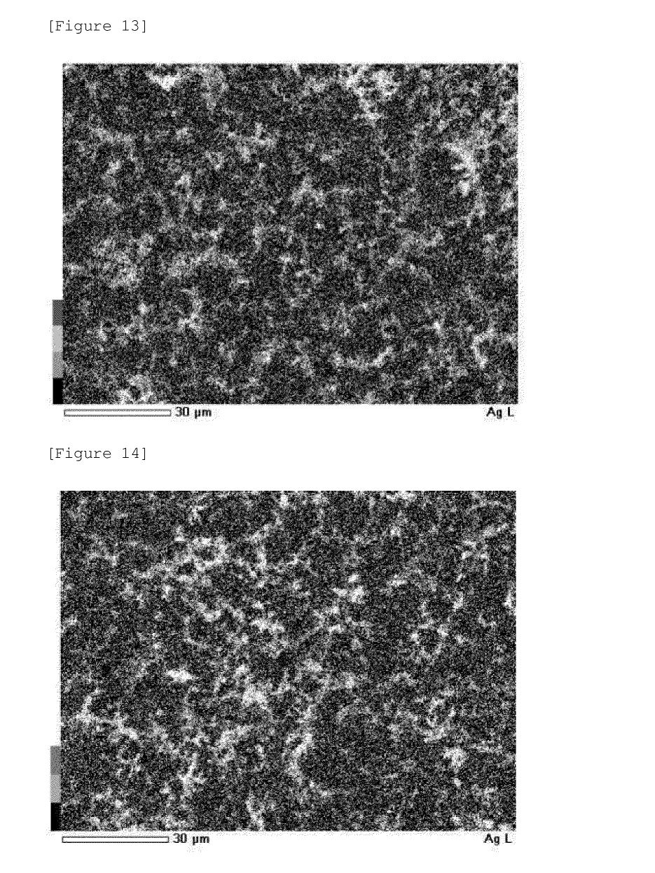

A relative density and an oxygen content were determined for the pre-sintered body, and a relative density, an oxygen content and a major axis length of a Ag phase were determined for the sintered body by measuring methods described below. Table 3 shows the results. Table 3 shows values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 13 shows one example of a mapping image of Ag in a pre-sintered body in a method for measuring a major axis length of a Ag phase as described below, and FIG. 14 shows one example of a mapping image of Ag in a sintered body in a method for measuring a major axis length of a Ag phase as described below.

### Example 5

### Production of Pre-Sintered Body

Mixed powder was prepared in a manner similar to the operation in Example 1 except that content ratios of Fe powder, Pt powder, Ag powder and C powder were changed to 20 mol %, 20 mol %, 10 mol % and 50 mol %, respectively.

The resultant mixed powder was fired using a spark plasma sintering apparatus under conditions similar to the conditions in Example 1 except that a heating rate was changed to 50° C./min, sintering temperature was changed to 850° C. and a sintering retention time was changed to 30 minutes to give a disc-shaped pre-sintered body having a diameter of 170 mm and a thickness of 5 mm.

### (Production of Sintered Body)

The resultant pre-sintered body was sealed into a pressure vessel made from a SUS tube, and subjected to hot isostatic press treatment using a hot isostatic press apparatus under conditions similar to the conditions in Example 1 to give a disc-shaped sintered body having a diameter of 165 mm and a thickness of 4 mm.

### (Determination of Values of Physical Properties of Pre-Sintered Body and Sintered Body)

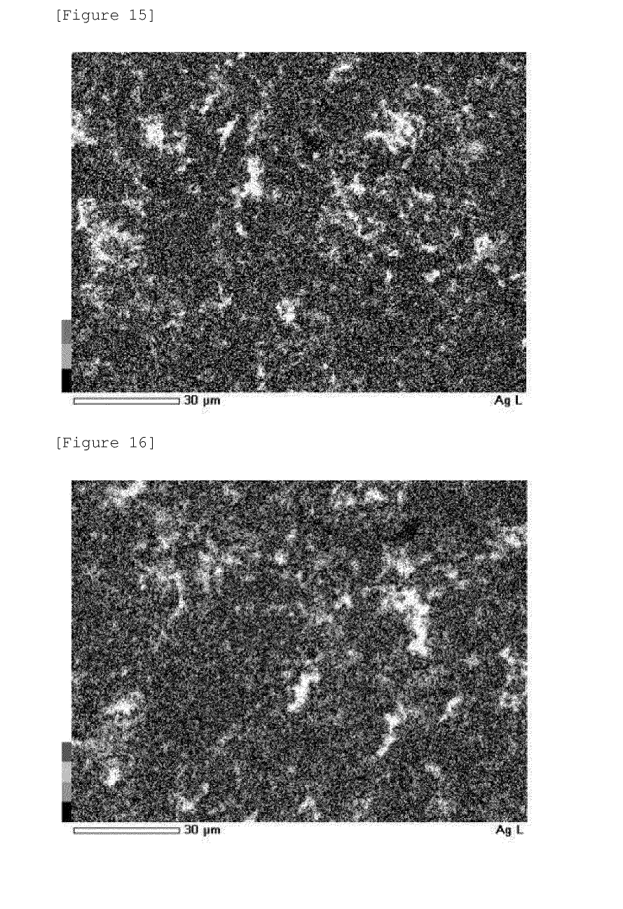

A relative density and an oxygen content were determined for the pre-sintered body, and a relative density, an oxygen content and a major axis length of a Ag phase were determined for the sintered body by measuring methods described below. Table 3 shows the results. Table 3 shows values of x, y and z when a composition of Fe, Pt, C and Ag of the sintered body is represented by an expression: (Fe_{x/100}Pt_{(100-x)/100})_{100-y-z}Ag_{y}C_{z}. Moreover, FIG. 15 shows one example of a mapping image of Ag in a pre-sintered body in a method for measuring a major axis length of a Ag phase as described below, and FIG. 16 shows one example of a mapping image of Ag in a sintered body in a method for measuring a major axis length of a Ag phase as described below.

TABLE 3

| | | | | Pre-sintered body | | | Sintered Body | | | | | |
|---|---|---|---|---|---|---|---|---|---|---|---|---|
| | | | Sintering | | | Major Axis | | | | | | Major Axis |
| | Sintering | Heating | Retention | Relative | Oxygen | Length of | | | | Relative | Oxygen | Length of |
| | Temperature | Rate | Time | Density | Content | Ag Phase | Composition | | | Density | Content | Ag Phase |
| | (° C.) | (° C./min) | (min) | (%) | (ppm) | (μm) | x | y | z | (%) | (ppm) | (μm) |
| Example 2 | 900 | 50 | 30 | 92.68 | 300 | 9.7 | 45 | 4 | 20 | 98.65 | 270 | 10.4 |
| Example 3 | 900 | 50 | 30 | 92.75 | 250 | 9.2 | 55 | 6 | 40 | 98.74 | 220 | 13.8 |
| Example 4 | 900 | 50 | 30 | 89.29 | 270 | 12.9 | 50 | 8 | 40 | 98.07 | 250 | 13.8 |
| Example 5 | 850 | 50 | 30 | 90.86 | 730 | 13.8 | 50 | 10 | 50 | 98.12 | 590 | 19.6 |

As shown in Table 3, even when a composition of Fe, Pt, C and Ag was changed, a sintered body having a high density, a low oxygen content and a uniform texture was obtained.

1. A sintered body comprising Fe, Pt, C and Ag, wherein, when a composition of Fe, Pt, C and Ag is represented by an expression: (Fe_{x/100}Pt_{(100-x)/100})_{100-y-z}Ag_{y}C_{z}, expressions: 35≦x≦65, 1≦y≦20 and 13≦z≦60 are satisfied, and wherein the sintered body has a relative density in the range of 95% or more, an oxygen content in the range of 700 ppm or less, and a major axis length of a phase composed of Ag being in the range of 20 μm or less.

2. The sintered body according to claim 1, produced by applying hot isostatic press treatment to a pre-sintered body comprising Fe, Pt, C and Ag.

3. The sintered body according to claim 1, produced by applying hot isostatic press treatment to a pre-sintered body comprising Fe, Pt, C and Ag as prepared by a spark plasma sintering process.

4. A sputtering target, obtained from the sintered body according to claim 1.

5. A sputtering target, obtained from the sintered body according to claim 2.

6. A sputtering target, obtained from the sintered body according to claim 3.
